(19) United States
(12) Patent Application Publication
(10) Pub. No.: US 2024/0044696 A1
(43) Pub. Date: Feb. 8, 2024

(54) METHOD FOR DECIMATING SAMPLES BY A FLOAT NUMBER AND ASSOCIATED DEVICE, SENSOR, AND MACHINE

(71) Applicant: Aktiebolaget SKF, Goteborg (SE)

(72) Inventors: Nicolas LIGNEE, Ia Membrolle sur Choisille (FR); Clément POULAILLEAU, Amboise (FR); Simon HUBERT, Tours (FR)

(21) Appl. No.: 18/357,254

(22) Filed: Jul. 24, 2023

(30) Foreign Application Priority Data
Aug. 2, 2022 (DE) 102022207988.4

(51) Int. Cl. G01H 1/14; H03H 17/02; G01H 1/00

(52) U.S. Cl. CPC G01H 1/14; H03H 17/0273; G01H 1/003

(57) ABSTRACT

The device (8) for decimating samples of a continuous signal by a float number. The device includes interpolating means (11) configured to determine intermediate samples. A determining means (12) is configured to determine intermediate set of samples comprising the samples and the intermediate samples. A filtering means (13) is configured to filter the intermediate set of samples to determine one final value from an odd number of consecutive samples of the intermediate set of samples and to remove frequencies below a first cut-off frequency (F3) equal to the predetermined sampling frequency divided by two within a predetermined tuning value.

### CROSS-REFERNCE TO RELATED APPLICATION

This application claims priority to German Application No. 102022207988.4, filed Aug. 2, 2022, the entirety of which is hereby incorporated by reference.

### FIELD

The present disclosure is directed to the decimation of continuous signals.

More particularly, the disclosure deals with a device for decimating samples of a continuous signal by a float number, a sensor comprising such a device, a rotating machine comprising such a sensor, and a method for decimating samples of a continuous signal by a float number.

### BACKGROUND

Wireless devices are increasingly implemented to monitor physical parameters of machines.

A wireless device may comprise a sensor for measuring for example vibrations, a sampler to sample the measurement signal generated by the sensor, a wireless transmitter to transmit the samples to a gateway for reconstructing measurements from the samples, and a battery to supply the sensor, the sampler and the transmitter.

Vibration measurements need a high sampling frequency to be accurate.

As the power consumption of the transmitter is dependent on the quantity of transmitted samples, the more the sampling frequency is high, the more the power consumption increase.

It is known to decimate the samples by an integer to reduce the quantity of samples to transmit in order to reduce the power consumption of the device while the quantity of transmitted samples is enough to have accurate measurements.

For some applications, decimating the samples by an integer is not adapted.

Decimating the samples by an integer chosen to be to high reduce the quantity of transmitted samples deteriorating the accuracy of the reconstructed measurements.

On the contrary, decimating the samples by an integer chosen to be to low increase the power consumption.

Consequently, the present disclosure intends to overcome these disadvantages.

### SUMMARY

According to an aspect, a method for decimating samples of a continuous signal by a float number is proposed.

The method comprises:
determining intermediate samples, each intermediate sample being centered between two consecutive samples and the value of each intermediate sample is determined by interpolating the values of the two consecutive samples, the samples being samples of the continuous signal at a predetermined sampling frequency,
determining an intermediate set of samples comprising the samples and the intermediate samples,
filtering the intermediate set of samples to determine one final value from an odd number of consecutive samples of the intermediate set of samples and to remove frequencies below a first cut-off frequency equal to the predetermined sampling frequency divided by two within a predetermined tuning value, the float number being equal to the odd number divided by two.

Decimating the samples by a float number permits to choose a decimating coefficient so that the transmitted data is accurate enough for further processing and so that the power consumption of the wireless sensor is reduced to increase the duration of the battery.

Further, the calculations are easy (additions and divisions) contributing to the duration of the battery.

Preferably, the value of each intermediate sample is equal to the average value of the values of the two consecutive samples.

According to an aspect, a device for decimating samples of a continuous signal by a float number is proposed.

The device comprises:
interpolating means configured to determine intermediate samples, each intermediate sample being centered between two consecutive samples and the value of each intermediate sample is determined by interpolating the values of the two consecutive samples, the samples comprising samples of the continuous signal at a predetermined sampling frequency,
determining means configured to determine an intermediate set of samples comprising the samples and the intermediate samples,
filtering means configured to filter the intermediate set of samples to determine one final value from an odd number of consecutive samples of the intermediate set of samples and to remove frequencies below a first cut-off frequency equal to the predetermined sampling frequency divided by two within a predetermined tuning value, the float number being equal to the odd number divided by two.

Advantageously, the filtering means comprise a polyphase filter.

Preferably, the value of each intermediate sample is equal to the average value of the values of the two consecutive associated samples.

According to another aspect, a sensor is proposed.

The sensor comprises sensing means, a sampler, and a device as defined below, the sensing means being configured to deliver a continuous signal representative of measurements, the sampler being configured to sample the continuous signal at the predetermined sampling frequency and to deliver the samples to the device.

Preferably, the sensor further comprises at least one filter having at least a second cut-off frequency and configured to filter the continuous signal representative of measurements, the filtering means being configured so that the first cut-off frequency and the second cut-off frequency are different by tuning the predetermined tuning value.

Advantageously, the sensor further comprises a wireless transmitter configured to transmit the final set of samples to a gateway.

Preferably, the sensing means are configured to measure vibrations.

According to another aspect, a rotating machine is proposed.

The rotating machine comprises a shaft and a sensor as defined below and measuring vibrations of the shaft, the predetermined sampling frequency being equal at least to twice the rotating frequency of the shaft.

### BRIEF DESCRIPTION OF THE DRAWINGS

Other advantages and features of the disclosure will appear on examination of the detailed description of embodiments, in no way restrictive, and the appended drawings in which:

FIG. 1 illustrates schematically a rotating machine according to the disclosure;

FIG. 2 illustrates schematically an example of a sensor according to the disclosure;

FIG. 3 illustrates schematically an embodiment of a device for decimating samples by a float number according to the disclosure;

FIG. 4 illustrates an example of a method for decimating samples by the float number according to the disclosure;

FIG. 5 illustrates schematically an example of an intermediate set of samples according to the disclosure; and

FIG. 6 illustrates schematically an example of final values transmitted by the sensor according to the disclosure.

### DETAILED DESCRIPTION

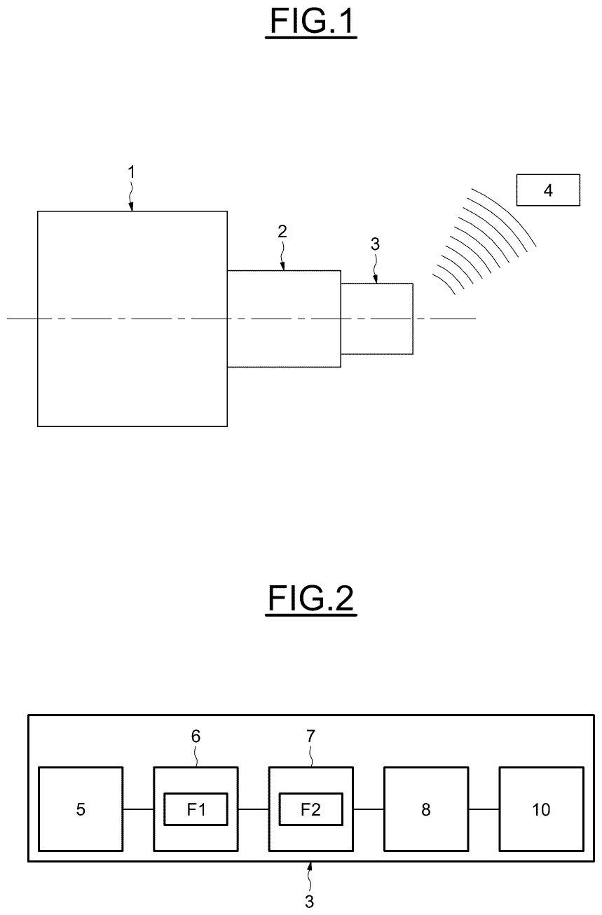

Reference is made to FIG. 1 which represents schematically a rotating machine 1.

The rotating machine 1 comprises a shaft 2 and a sensor 3 mounted on the shaft 2 to measure vibrations on the shaft 2.

The sensor 3 transmits wirelessly measured vibration values to a gateway 4.

In variant, the sensor 3 may measure another physical parameter, for example the speed of the shaft 2.

FIG. 2 represents schematically an embodiment of the sensor 3.

The sensor 3 comprises sensing means 5 comprising a vibration sensor for measuring the vibrations on the shaft 2.

The sensor 3 may further comprise a filter 6 having a first cut-off frequency F1 to filter a continuous signal representative of measurements delivered by the sensing means 5.

The filter 6 may be a high pass filter to eliminate the frequencies of the delivered signal below the first cut-off frequency F1.

The sensor 3 comprises a sampler 7 to generate samples Si at a sampling frequency F2, i being a non-nil integer.

The sensor 3 further comprises a device 8 for decimating samples generated by the sampler 7 by a float number and a wireless transmitter 10.

An input of the device 8 is connected to an output of the sampler 7 and an output of the device 8 is connected to the transmitter 10 so that the transmitter 10 transmits to the gateway 4 the decimated samples generated by the device 8.

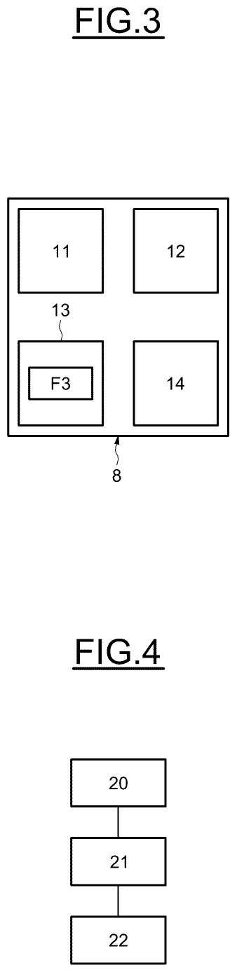

FIG. 3 represents schematically an embodiment of the device 8.

The device 8 comprises interpolating means 11 to determine intermediate samples SIi.

The device 8 further comprises determining means 12 to determine an intermediate set of samples comprising samples Si and intermediate samples SIi.

The device 8 comprises filtering means 13 to filter the intermediate set of samples delivered by the determining means 12.

The device 8 further comprises a processing unit 14 implementing the interpolating means 11, the determining means 12, and the filtering means 13.

FIG. 4 illustrates an example of a method for decimating the samples Si by a float number.

It is assumed that the device 8 has received ten samples Si, i varying between one and ten.

In an interpolating step 20, the interpolating means 11 determine the intermediate samples SIi.

Each intermediate sample SIi is centered between two consecutive samples Si, Si+1.

The value of each intermediate sample SIi is determined by interpolating the values of the two consecutive samples Si, Si+1.

The value of each intermediate sample SIi may be equal to the average value of the values of the two consecutive samples Si, Si+1.

In an assembling step 21, the determining means 12 determine the intermediate set of samples comprising the samples Si and the intermediate samples SIi.

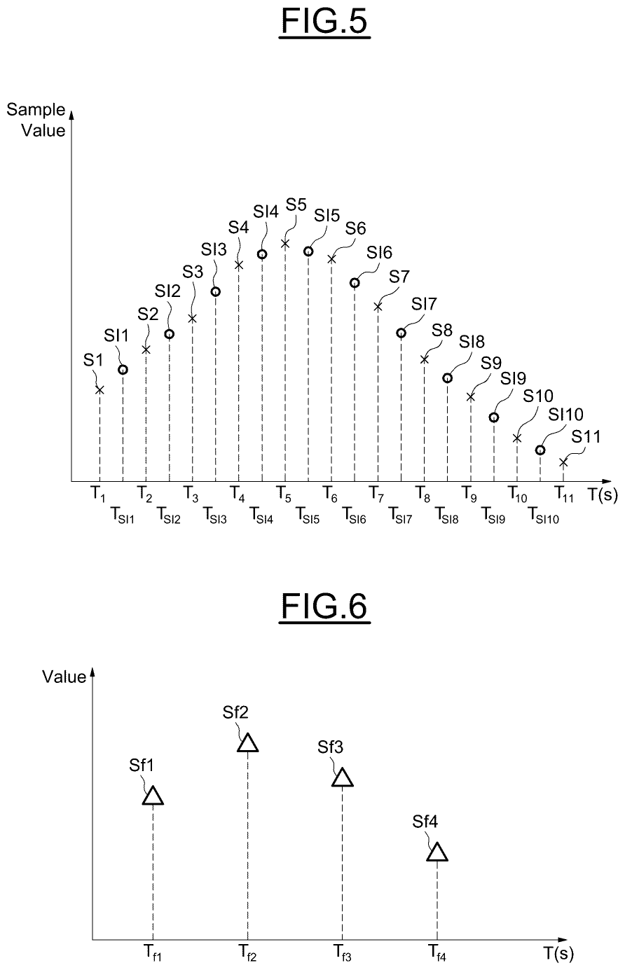

FIG. 5 illustrates an example of the intermediate set of samples according to the sampling time Tᵢ of the samples Si and the determined sampling time T_{SIi}, i varying between one and ten.

The determined sampling time T_{SIi} is chosen so that each intermediate sample SIi is centered between the two sampling times Tᵢ, Ti+1 of the two consecutive samples Si, Si+1.

In a filtering step 21 (FIG. 4), the filtering means 13 filter the intermediate set of samples comprising the samples Si and intermediate sample SIi to determine one final value Sfj from an odd number of consecutive samples Si, SIi of the intermediate set, j being a non-nil integer.

The samples Si are decimated by the float number equal to the odd number divided by two.

The final value Sfi is obtained by adding the odd number of consecutive samples Si, SIi of the intermediate set, each sample Si and intermediate SIi being weighted by at least one coefficient.

The odd number is chosen so that the accuracy of a signal reconstructed from the final values Sfj is enough for further processing.

The odd number is for example equal to five so that four final value Sfj, j varying from one to four are defined.

Further, the filtering means 13 filter the intermediate set of samples to remove frequencies below a second cut-off frequency F3 equal to the predetermined sampling frequency F2 divided by two within a predetermined tuning value VAL to observe the Nyquist sampling criterion to be able to determine the measurements from the final values Sfj.

A first final value Sf1 is determined from the samples S1, S2, S3 and the intermediate samples SI1, SI2.

A second final value Sf2 is determined from the samples S4, S5 and the intermediate samples SI3, SI4, SI5.

A third final value Sf3 is determined from the samples S6, S7, S8 and the intermediate samples SI6, SI7.

A fourth final value Sf4 is determined from the samples S9, S10 and the intermediate samples SI8, SI9, SI10.

The predetermined tuning value VAL is chosen so that the second cut-off frequency F3 is different from the first cut-off frequency F1 to avoid mitigation of the final values Sfj.

When the absolute value of the difference between first cut-off frequency F1 and the sampling frequency F2 is greater than a discrimination value, the predetermined tuning value VAL is nil.

The discrimination value is for example equal to the sampling frequency F2 divided by two.

FIG. 6 illustrates an example of the final values Sf1, Sf2, Sf3, Sf4 according to the sampling time T_{f1}, T_{f2}, T_{f3}, T_{f4.}

The sampling time T_{f1} of the first final value Sf1 is equal to the sampling time T₃ of the sample T3.

The sampling time T_{f2} of the second final value Sf2 is equal to the sampling time T_{SI5} of the intermediate sample SI5.

The sampling time T_{f3} of the third final value Sf3 is equal to the sampling time T₈ of the sample T8.

The sampling time T_{f4} of the fourth final value Sf4 is equal to the sampling time T_{SI10} of the intermediate sample SI10.

The filtering means may comprise a polyphase filter to decimate and filter the intermediate samples SIi.

The coefficients of the filter are chosen according to the sampling frequency 2, the second cut-off frequency F3.

The final values Sf1, Sf2, Sf3, Sf4 are transmitted by the transmitter 10 to the gateway 4.

Decimating the samples by a float number permits to choose a decimating coefficient so that the transmitted data is accurate enough for further processing and so that the power consumption of the wireless sensor is reduced to increase the duration of the battery.

Further, the calculations implemented by the device 8 are easy (additions and divisions) reducing the power consumption of the processing unit to preserve the duration of the battery.

What is claimed is:

1. A method for decimating samples of a continuous signal by a float number, the method comprising:
determining intermediate samples, each intermediate sample being centered between two consecutive samples and the value of each intermediate sample is determined by interpolating the values of the two consecutive samples, the samples being samples of the continuous signal at a predetermined sampling frequency,
determining an intermediate set of samples comprising the samples and the intermediate samples,
filtering the intermediate set of samples to determine one final value from an odd number of consecutive samples of the intermediate set of samples and to remove frequencies below a first cut-off frequency equal to the predetermined sampling frequency divided by two within a predetermined tuning value, the float number being equal to the odd number divided by two.

2. The method according to claim 1, wherein the value of each intermediate sample is equal to the average value of the values of the two consecutive samples.

3. A device for decimating samples of a continuous signal by a float number, the device comprising:
interpolating means configured to determine intermediate samples, each intermediate sample being centered between two consecutive samples and the value of each intermediate sample is determined by interpolating the values of the two consecutive samples, the samples comprising samples of the continuous signal at a predetermined sampling frequency,
determining means configured to determine intermediate set of samples comprising the samples and the intermediate samples,
filtering means configured to filter the intermediate set of samples to determine one final value from an odd number of consecutive samples of the intermediate set of samples and to remove frequencies below a first cut-off frequency equal to the predetermined sampling frequency divided by two within a predetermined tuning value, the float number being equal to the odd number divided by two.

4. The device according to claim 3, wherein the filtering means comprise a polyphase filter.

5. The device according to claim 3, wherein the value of each intermediate sample is equal to the average value of the values of the two consecutive associated samples.

6. The device according to claim 4, wherein the value of each intermediate sample is equal to the average value of the values of the two consecutive associated samples.

7. A sensor comprising:
a sensing means,
a sampler, and
a device according to claim 3, the sensing means being configured to deliver a continuous signal representative of measurements, the sampler being configured to sample the continuous signal at the predetermined sampling frequency and to deliver the samples to the device.

8. The sensor according to claim 7, wherein the filtering means comprise a polyphase filter.

9. The sensor according to claim 8, wherein the value of each intermediate sample is equal to the average value of the values of the two consecutive associated samples.

10. The sensor according to claim 9, further comprising at least one filter having at least a second cut-off frequency and configured to filter the continuous signal representative of measurements, the filtering means being configured so that the first cut-off frequency and the second cut-off frequency are different by tuning the predetermined tuning value.

11. The sensor according to claim 10, further comprising a wireless transmitter configured to transmit the final set of samples to a gateway.

12. The sensor according to claim 11, wherein the sensing means are configured to measure vibrations.

13. The sensor according to claim 7, further comprising at least one filter having at least a second cut-off frequency and configured to filter the continuous signal representative of measurements, the filtering means being configured so that the first cut-off frequency and the second cut-off frequency are different by tuning the predetermined tuning value.

14. The sensor according to claim 7, further comprising a wireless transmitter configured to transmit the final set of samples to a gateway.

15. The sensor according to claim 7, wherein the sensing means are configured to measure vibrations.

16. The sensor according to claim 14, wherein the sensing means are configured to measure vibrations.

17. A rotating machine comprising:
a shaft, and
a sensor according to claim 15 for measuring vibrations of the shaft, the predetermined sampling frequency being equal at least to twice the rotating frequency of the shaft.
